(19) United States
(12) Patent Application Publication
(10) Pub. No.: US 2010/0164115 A1
(43) Pub. Date: Jul. 1, 2010

(54) SEMICONDUCTOR CHIP PACKAGE

(76) Inventor: Jung-Hyun Yo, Yongin-si (KR)

Correspondence Address: SHERR & VAUGHN, PLLC, 620 HERNDON PARKWAY, SUITE 320, HERNDON, VA, 20170, US

(21) Appl. No.: 12/649,257

(22) Filed: Dec. 29, 2009

(30) Foreign Application Priority Data
Dec. 31, 2008 (KR) 10-2008-0138066

(51) Int. Cl. H01L 23/498; H01L 21/60

(52) U.S. Cl. 257/773; 438/121; 257/E21.506; 257/E23.06; 257/784

(57) ABSTRACT

A device and/or method relating to semiconductor technology. A semiconductor chip package may include dual line type input/output (I/O) pads. A semiconductor chip package may include a core area. A semiconductor chip package may include input/output (I/O) pads arranged on and/or over an outside of a core area, which may signal input/output to and/or from a core area. A semiconductor chip package may have input/output (I/O) pads including dual lines.

The present application claims priority under 35 U.S.C. 119 to Korean Patent Application No. 10-2008-0138066 (filed on Dec. 31, 2008) which is hereby incorporated by reference in its entirety.

### BACKGROUND

Embodiments relate to semiconductor technology. Some embodiments relate to a semiconductor chip package including dual line type input/output (I/O) pads.

Wire bonding technology may be used to fabricate a semiconductor chip package. In wire bonding technology, a chip may include a logical system of macros and/or digital logics which may have various functions and/or characteristics. Intellectual Properties (IP) may be in charge of signal input/output interface with a semiconductor chip, and/or an input/output IP (I/O IP) may be used. An I/O IP may be positioned at a boundary, which may result from the nature of a semiconductor chip package technology. Chip designers may study a chip performance in view of positions and/or distances of IPs, and/or may intend to design a minimum sized chip with maximized performance.

Physical structures of an I/O IP may include an In-line type I/O pad and/or a staggered type I/O pad. Such I/O pads may include rectangular structures, physically. Example FIG. 1 illustrates a semiconductor chip package including in-line type I/O pads. Example FIG. 2 illustrates a semiconductor chip package including staggered type I/O pads. Referring to FIG. 1, a physically rectangular in-line type may have a relatively large length to width ratio. Referring to FIG. 2, a staggered type may also be physically rectangular and/or may have a smaller length to width ratio relative to an in-line type.

Since an in-line type I/O pad may have relatively many transistors of macros and/or digital logics, and/or relatively many active and/or passive devices, transistors and/or devices may occupy a relatively large portion of an entire area of a chip. There may be an effort needed to reduce a number of signal I/O pins of a chip, which may influence a size of a chip. An in-line type I/O pad may have a physical structure in which a width thereof may be relatively large and/or a height thereof may be relatively small, to arrange a plurality of pads on and/or over a line in a cell having a plurality of pads. A staggered type I/O pad may require relatively many I/O pins to interface with an outside of a chip even though a number of devices may be small. A staggered type I/O pad may have a physical structure in which a width thereof may be relatively small and/or a height thereof may be relatively large.

Therefore, a chip designer may be required to determine a type of I/O pad considering a number of devices, a ratio of an area a core region may occupy on and/or over a chip, and/or a number and/or size of I/O pins which may be required to interface with an outside of a chip. Development of an I/O pad of a new structure may be needed to embody a minimum chip size and/or a maximum performance.

### SUMMARY

Embodiments relate to semiconductor technology. Some embodiments relate to a semiconductor chip package. According to embodiments, a semiconductor chip package may include dual line type I/O pads. In embodiments, a semiconductor chip package may include a minimum chip size and/or maximized performance.

According to embodiments, a semiconductor chip package may include a core area. In embodiments, a semiconductor chip package may include input/output (I/O) pads. In embodiments, a semiconductor chip package may include input/output (I/O) pads arranged on and/or over an outside of a core area which may signal input/output to and/or from a core area.

According to embodiments, input/output (I/O) pads may include dual lines. In embodiments, dual lines may include an inner line having a first group of input/output pads, and/or an outer line having a second group of input/output pads. In embodiments, input/output pads of an inner line and/or input/output pads of an outer line may be arranged to straddle on and/or over, and/or opposite to, each other.

### DRAWINGS

FIG. 1 illustrates a semiconductor chip package having in-line type I/O pads.

FIG. 2 illustrates a semiconductor chip package having staggered type I/O pads.

FIG. 3 illustrates a semiconductor chip package having dual line type I/O pads in accordance with embodiments.

FIG. 4 illustrates dual line type I/O pads and an example of I/O routing thereof of a semiconductor package in accordance with embodiments.

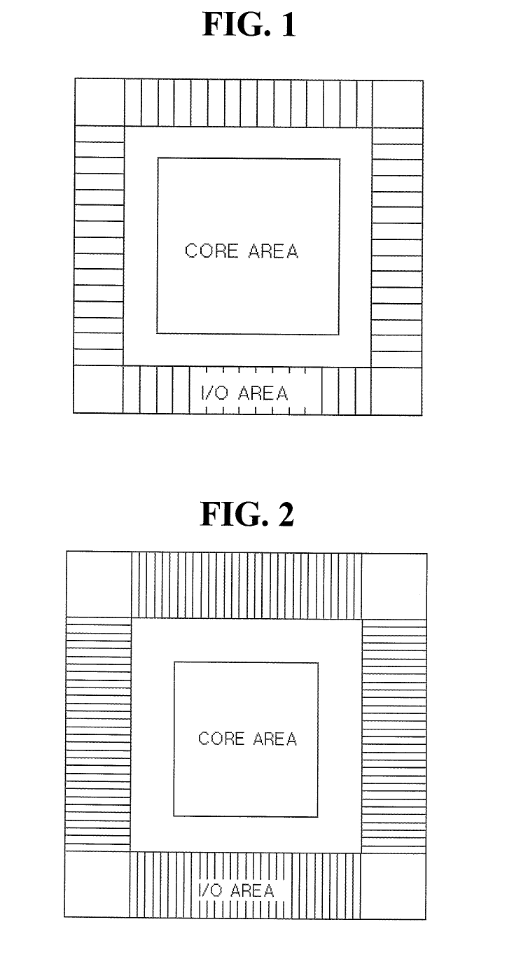

### DESCRIPTION

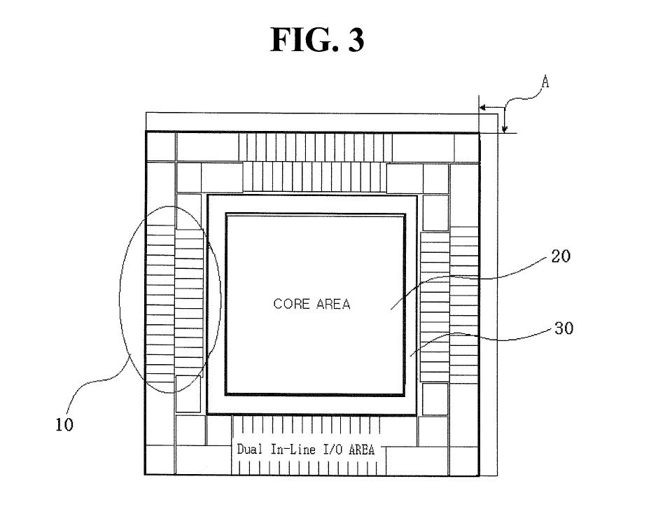

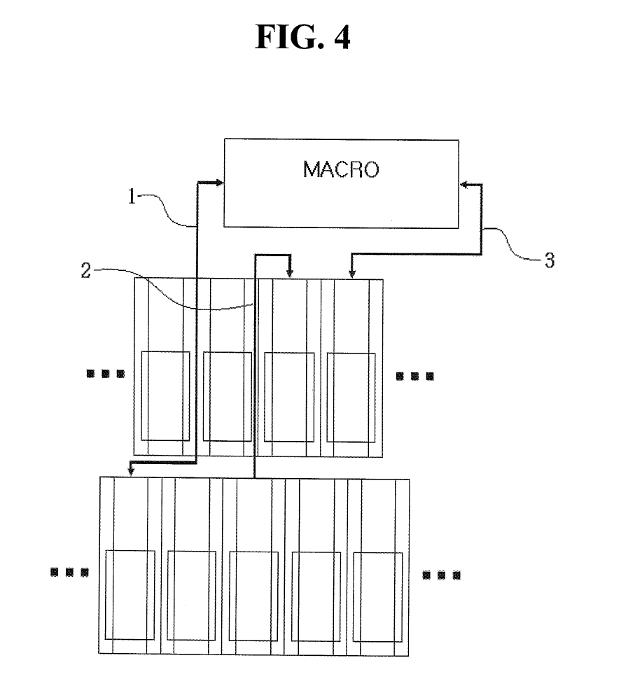

Embodiments relate to semiconductor technology. Some embodiments relate to a semiconductor chip package including dual line type input/output (I/O) pads. Referring to example FIG. 3, a semiconductor chip package having dual line type I/O pads in accordance with embodiments is illustrated. Referring to example FIG. 4, dual line type I/O pads and/or an example of I/O routing thereof of a semiconductor package in accordance with embodiments is illustrated.

Referring to FIG. 3, a semiconductor chip package may include chip core area 20 and/or I/O pads 10 on and/or over an I/O area at an outside of core area 20. According to embodiments, I/O pads 10 may be arranged on and/or over an outside of core area 20, which may make signal input/output to/from core area 20. In embodiments, there may be a reserved space between core area 20 and the I/O pads 10. In embodiments, I/O pads 10 may have dual lines including inner lines having a first group of I/O pads 10, and/or outer lines having a second group of I/O pads 10.

According to embodiments, inner lines may be arranged on and/or over a side of a core area, and/or outer lines may be arranged on and/or over an outside of inner lines. In embodiments, I/O pads 10 of inner lines and/or I/O pads 10 of outer lines may be arranged to straddle on and/or over, and/or opposite to, each other. In embodiments, I/O pads 10 of inner lines and/or I/O pads 10 of outer lines may have a width substantially the same as in-line type I/O pads. In embodiments, I/O pad 10 in accordance with embodiments may have a length shorter than an in-line type I/O pad.

According to embodiments, dual line type I/O pads may permit a reduction in the relative size of a semiconductor chip package, for example by A. In embodiments, dual line type I/O pads may have a relatively large number of pads owing to a dual line arrangement. In embodiments, dual line type I/O pads may have an in-line type I/O pads structure applied thereto. In embodiments, dual line type I/O pads may be used when a relatively large number of I/O pins may be required for external interfacing, such as staggered type I/O pads.

Referring to FIG. 4, dual line type I/O pads and/or an example of I/O routing thereof of a semiconductor package in accordance with embodiments is illustrated. According to embodiments, input/output routing structures 1, 2 and/or 3 may be provided. In embodiments, a routing between an inner line and an outer line may be made. In embodiments, inner lines and/or outer lines may construct logical systems of macros and/or digital logics, which may have a variety of functions, characteristics and/or interfaces of signal input/output, which may be independent. In embodiments, dual line type I/O pads may include metal pads of sizes different from one another.

According to embodiments, unlike in-line type I/O pads and/or staggered type I/O pads, dual line I/O pads may permits minimized size of a semiconductor chip package, and/or may have maximized performance, for example resulting from dual line I/O pads substantially maintaining electric characteristics even if physical structure may change. In embodiments, I/O pads for the semiconductor chip package of the present invention may be related to in-line type pad structure, but the configuration of, not a single, but a dual line, may minimize the drawback that an in-line type pad structure may be used when a relatively small number of pins may be required to signal input/output.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a core area; and
input/output pads arranged over an outside of a core area configured to signal at least one of an input and an output to and from said core area.

2. The apparatus of claim 1, wherein said input/output pads comprise dual lines.

3. The apparatus of claim 2, wherein said dual lines comprise an inner line including a first group of input/output pads and an outer line including a second group of input/output pads.

4. The apparatus of claim 3, wherein said input/output pads of said inner line and said input/output pads of said outer line are arranged to straddle over each other.

5. The apparatus of claim 4, wherein said input/output pads of said inner line and said input/output pads of said outer line are arranged opposite to each other.

6. The apparatus of claim 3, wherein said input/output pads of said inner line are arranged at a side of said core area, and said input/output pads of said outer line are arranged at an outside of said input/output pads of said inner line.

7. The apparatus of claim 3, wherein said input/output pads of said inner line and said input/output pads of said outer line comprise an in-line type which is physically rectangular having a length greater than a width.

8. The apparatus of claim 7, wherein said input/output pads of said inner line and said input/output pads of said outer line comprises a width substantially the same as a width of said in-line type input/output pads and a length shorter than a length of said in-line type input/output pads.

9. The apparatus of claim 1, comprising a reserved space between said input/output pads and said core area.

10. The apparatus of claim 1, comprising a semiconductor chip package.

11. A method comprising:
forming a core area; and
forming input/output pads arranged over an outside of a core area configured to signal at least one of an input and an output to and from said core area.

12. The method of claim 11, wherein said input/output pads comprise dual lines.

13. The method of claim 12, wherein said dual lines comprise an inner line including a first group of input/output pads and an outer line including a second group of input/output pads.

14. The method of claim 13, wherein said input/output pads of said inner line and said input/output pads of said outer line are arranged to straddle over each other.

15. The method of claim 14, wherein said input/output pads of said inner line and said input/output pads of said outer line are arranged opposite to each other.

16. The method of claim 13, wherein said input/output pads of said inner line are arranged at a side of said core area, and said input/output pads of said outer line are arranged at an outside of said input/output pads of said inner line.

17. The method of claim 13, wherein said input/output pads of said inner line and said input/output pads of said outer line comprise an in-line type which is physically rectangular having a length greater than a width.

18. The method of claim 17, wherein said input/output pads of said inner line and said input/output pads of said outer line comprises a width substantially the same as a width of said in-line type input/output pads and a length shorter than a length of said in-line type input/output pads.

19. The method of claim 11, comprising a reserved space between said input/output pads and said core area.

20. The method of claim 11, comprising a semiconductor chip package.
